(19) United States
(12) Patent Application Publication
(10) Pub. No.: US 2023/0068840 A1
(43) Pub. Date: Mar. 2, 2023

(54) GRINDING APPARATUS

(71) Applicant: DISCO CORPORATION, Tokyo (JP)

(72) Inventor: Yujiro SUDO, Tokyo (JP)

(21) Appl. No.: 17/820,836

(22) Filed: Aug. 18, 2022

(30) Foreign Application Priority Data
Sep. 2, 2021 (JP) 2021-142949

(51) Int. Cl. B24B 51/00; B24B 49/12; B24B 41/06

(52) U.S. Cl. CPC B24B 51/00; B24B 49/12; B24B 41/06

(57) ABSTRACT

A grinding apparatus includes a chuck table, a grinding unit, a moving mechanism for moving the chuck table and the grinding unit relatively to each other in predetermined directions, a detector for emitting a web-shaped laser beam and detecting a reflected laser beam thereof, and a control unit. The control unit includes a storing section for storing a relative vertical position of a holding surface to a grinding wheel along the predetermined directions, a first distance calculating section for calculating a first distance in one of the predetermined directions from the detector to a lower surface of the at least one of grindstones, and a lower surface position calculating section for calculating the position of a lower surface of the at least one of grindstones to the holding surface on the basis of the relative vertical position stored in the storing section and the first distance calculated.

### BACKGROUND OF THE INVENTION

### Field of the Invention

The present invention relates to a grinding apparatus for grinding a workpiece.

### Description of the Related Art

Various types of electronic equipment such as mobile phones and personal computers incorporate semiconductor device chips. Semiconductor device chips are fabricated by processing a semiconductor wafer (hereinafter simply referred to as a “wafer”) where a grid of projected dicing line is established on a face side thereof and a plurality of devices such as integrated circuits (ICs) are formed in respective areas demarcated on the face side by the projected dicing lines. In recent years, there is sometimes performed a process of grinding a reverse side of a wafer with a grinding apparatus to thin down the wafer to a predetermined thickness before the wafer is divided into semiconductor device chips along projected dicing lines thereon by a cutting apparatus, in order to make the semiconductor device chips smaller in size and weight.

The grinding apparatus includes a chuck table for holding the wafer under suction on a holding surface thereof and a grinding unit disposed above the chuck table. The grinding unit includes a cylindrical spindle extending vertically along Z-axis directions. An annular grinding wheel is mounted on the lower end of the spindle. When the grinding apparatus operates in an infeed grinding mode, the chuck table with the wafer held under suction thereon is rotated about its central axis, and at the same time the grinding wheel that is being rotated about its central axis by the spindle is lowered at a predetermined speed in one of the Z-axis directions, i.e., is grinding-fed.

For accurately controlling the amount of material to be ground off the wafer and the thickness to which the wafer is to be finished, it is necessary to carry out a setting-up process to enable the grinding apparatus to recognize the position of the lower surfaces of grindstones of the grinding wheel with respect to the holding surface of the chuck table as a vertical or heightwise reference, i.e., a home position. The setting-up process is performed, for example, when the grinding wheel that has been used is replaced with a fresh one or when the grinding wheel has been worn after use. Further, the setting-up process is also performed if necessary, when the chuck table that has been used is replaced with a fresh one or after the holding surface of the chuck table has been self-ground, i.e., ground by the grindstones.

It has been general practice to perform a manual setting-up process in the setting-up process for the grinding apparatus. According to the manual setting-up process, an operator places a reference piece, known as a block gage, having a predetermined thickness on the holding surface of the chuck table, and then the grinding unit is grinding-fed, to bring the lower surfaces of the grindstones into contact with a predetermined upper surface of the reference piece (see, for example, JP 2013-253837A).

### SUMMARY OF THE INVENTION

However, the manual setting-up process requires the operator to work in an increased number of man-hours. Each time the manual setting-up process is performed, the reference piece may possibly damage the grinding apparatus or the grinding wheel due to a mistake that the operator may make while working.

The present invention has been made in view of the above problems. It is an object of the present invention to provide a grinding apparatus that allows the operator to work in a reduced number of man-hours in a setting-up process and that reduces the possibility that the operator may make a mistake in a manual setting-up process.

In accordance with an aspect of the present invention, there is provided a grinding apparatus for grinding a workpiece, including a chuck table rotatable about a predetermined rotational axis, the chuck table having a holding surface for holding the workpiece thereon, a grinding unit that is disposed above the chuck table and has a spindle, wherein a grinding wheel is to be mounted on a lower end of the spindle and the grinding wheel includes an annular wheel base and a plurality of grindstones disposed on a lower surface of the wheel base circumferentially therealong, a moving mechanism for moving the chuck table and the grinding unit relatively to each other in predetermined directions to bring the holding surface and the grinding wheel closer to each other, a detector having a light emitter and a light detector, wherein the light emitter includes a lens and a light-emitting element and the light emitter can apply a web-shaped laser beam to at least one of the grinding stones and a portion of the lower surface of the wheel base that is adjacent to the at least one of the grindstones radially of the grinding wheel, the light detector including a light-detecting element for detecting a reflected laser beam reflected of the web-shaped laser beam from the at least one of the grinding stones and the portion of the lower surface of the wheel base, and a control unit for controlling the grinding unit, the moving mechanism, and the detector, the control unit having a processor and a memory. The control unit includes a holding surface position storing section for storing a relative vertical position of the holding surface with respect to the grinding wheel along the predetermined directions, a first distance calculating section for calculating a first distance in one of the predetermined directions from the detector to a lower surface of the at least one of the grindstones, and a lower surface position calculating section for calculating a position of the lower surface of the at least one of the grindstones with respect to the holding surface on the basis of the relative vertical position of the holding surface stored in the holding surface position storing section and the first distance calculated by the first distance calculating section.

Preferably, it is assumed that, when a grindstone of the plurality of grindstones is held in contact with an upper surface of a reference piece placed on the holding surface, the relative vertical position in one of the predetermined directions of the holding surface with respect to the grinding wheel is represented by P_{A}, the thickness from the upper surface of the reference piece to a lower surface thereof is represented by D, and the first distance from the detector to the lower surface of the at least one of the grindstones is represented by B₁, and that, when the reference piece is removed from the holding surface, the first distance from the detector to the lower surface of the at least one of the grindstones is represented by Z₁, and the lower surface position calculating section calculates the vertical position P_{C} of the lower surface of the at least one of the grindstones with respect to the holding surface when the reference piece is removed from the holding surface, according to the equation (1) Z₃=Z₁−(B₁−D) and the equation (2) P_{C}=P_{A}+Z₃.

Preferably, the control unit further includes a grinding edge length calculating section for calculating a grinding edge length of the at least one of the grindstones on the basis of a second distance from the detector to the lower surface of the wheel base and the first distance from the detector to the lower surface of the at least one of the grindstones.

Preferably, the control unit further includes a center deviation calculating section for calculating a deviation between a center of rotation of the spindle and a center of a circle defined by an outer circumferential side surface of the grindstones on the basis of data of the reflected laser beam detected by the detector at a time at which the grinding wheel is rotated about its central axis.

The control unit of the grinding apparatus according to the aspect of the present invention can calculate the position of the lower surface of the at least one of the grindstones with respect to the holding surface, using the detector that emits and detect laser beams. Consequently, the number of man-hours required for the operator to place the reference piece on the holding surface and then retrieve the reference piece from the holding surface is eliminated. Further, the possibility that the operator may make a mistake in the manual setting-up process is lowered.

The above and other objects, features and advantages of the present invention and the manner of realizing them will become more apparent, and the invention itself will best be understood from a study of the following description and an appended claim with reference to the attached drawings showing a preferred embodiment of the invention.

### BRIEF DESCRIPTION OF THE DRAWINGS

FIG. 1 is a perspective view of a grinding apparatus according to an embodiment of the present invention;

FIG. 2 is an enlarged perspective view of a chuck table and a laser displacement gage of the grinding apparatus;

FIG. 3 is a side elevational view, partly in cross section, illustrating a general make-up of the laser displacement gage;

FIG. 4 is an enlarged perspective view of the chuck table, a grinding wheel, and the laser displacement gage;

FIG. 5 is a plan view of the chuck table, the grinding wheel, and the laser displacement gage;

FIG. 6 is a flowchart of a setting-up process for the grinding apparatus;

FIG. 7 is a side elevational view, partly in cross section, illustrating a first measuring step;

FIG. 8 is a graph illustrating the distance from a holding surface of the chuck table and the laser displacement gage to lower surfaces of grindstones;

FIG. 9 is a side elevational view, partly in cross section, illustrating a second measuring step;

FIG. 10 is a plan view illustrating a deviation of the center of a circle defined by an outer circumferential side surface of the grindstones from the center of rotation of a spindle of the grinding apparatus; and

FIG. 11 is a graph illustrating variations over time in the position of an outer circumferential edge of a lower surface of a grindstone.

### DETAILED DESCRIPTION OF THE PREFERRED EMBODIMENT

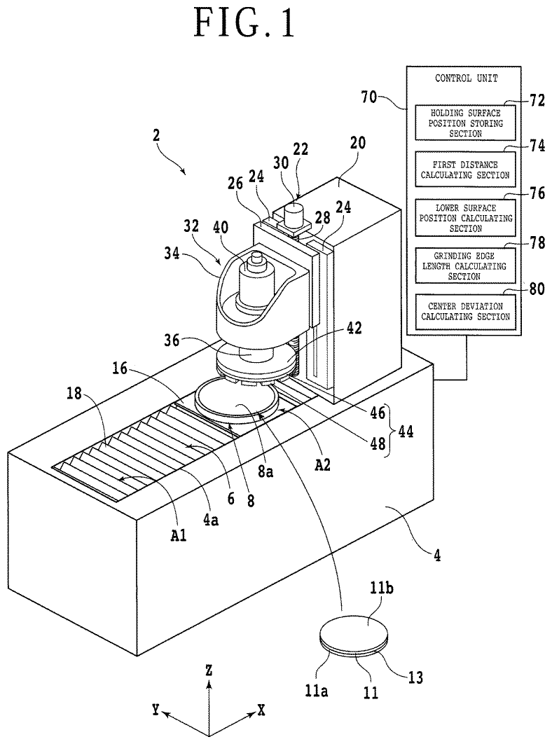

A grinding apparatus according to a preferred embodiment of the present invention will be described hereinbelow with reference to the accompanying drawings. FIG. 1 illustrates the grinding apparatus, denoted by 2, according to the present embodiment. Throughout FIG. 1 and some of the other figures, X-axis directions along an X-axis, i.e., forward and rearward directions, Y-axis directions along a Y-axis, i.e., leftward and rightward directions, and Z-axis directions along a Z-axis, i.e., upward and downward directions, extend perpendicularly to each other. For illustrative purposes, some components of the grinding apparatus 2 have ends, sides, areas, etc. referred to as front or forward ends, sides, areas, etc. facing in one of the Y-axis directions, i.e., a rightward Y-axis direction, and ends, sides, areas, etc. referred to as rear or rearward ends, sides, areas, etc. facing in the other of the Y-axis directions, i.e., a leftward Y-axis direction. The grinding apparatus 2 is of the manual type where a wafer, i.e., a workpiece, 11 is loaded and unloaded manually by the operator. However, the grinding apparatus 2 may be of the fully automatic type where the wafer 11 is loaded, unloaded, ground, and cleaned automatically.

The grinding apparatus 2 has a base 4 that supports components of the grinding apparatus 2 thereon. The base 4 has an upper surface having a rectangular opening 4a defined therein that has a longitudinal axis extending along the X-axis directions. The opening 4a is positioned above a ball-screw-type X-axis moving mechanism 6 whose general position is indicated in FIG. 1. The X-axis moving mechanism 6 has a pair of horizontal guide rails, not illustrated, extending parallel to each other along the X-axis directions. An X-axis movable plate, not illustrated, is slidably disposed on the guide rails.

A nut, not illustrated, is fixed to a lower surface of the X-axis movable plate. A ball screw, not illustrated, that is disposed between the guide rails and extends substantially parallel to the X-axis directions is rotatably threaded through the nut. A rotary actuator, not illustrated, such as a stepping motor is coupled to an end of the ball screw. When the rotary actuator is energized, the X-axis movable plate is moved in one of the X-axis directions. Another rotary actuator, not illustrated, such as an electric motor, for rotating a chuck table 8 shaped as a circular plate about its central axis is mounted on an upper surface of the X-axis movable plate. A drive pulley, not illustrated, is coaxially mounted on an output shaft of the rotary actuator for rotating the chuck table 8. As described later, the chuck table 8 serves to hold the wafer 11 thereon.

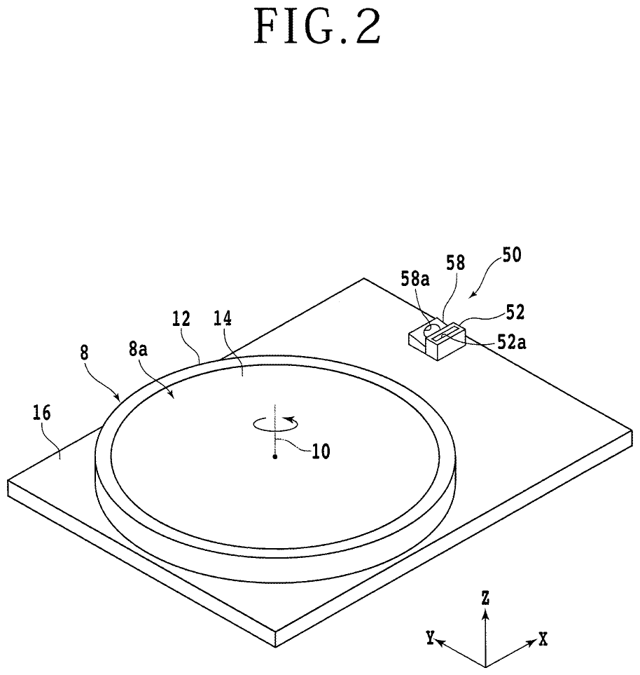

A rotor, not illustrated, that is rotatable about its central axis aligned with a rotational axis 10 (see FIG. 2) is also provided over the upper surface of the X-axis movable plate. The rotor has an upper end coupled to a lower surface of the chuck table 8. A driven pulley, not illustrated, is coaxially mounted on a lower end portion of the rotor. An endless belt, not illustrated, is trained around the drive pulley on the output shaft of the rotary actuator and the driven pulley on the lower end portion of the rotor. When the rotary actuator is energized, the chuck table 8 is rotated about the rotational axis 10 (see FIG. 2).

The chuck table 8 is rotatably supported on a table base, not illustrated, by a bearing, not illustrated. The table base is supported on the upper surface of the X-axis movable plate by a tilt adjusting mechanism, not illustrated. The tilt adjusting mechanism has a fixed shaft, not illustrated, and two movable shafts, not illustrated, whose lengths are variable along the Z-axis directions, so that the tilt of the table base and the chuck table 8 can be adjusted.

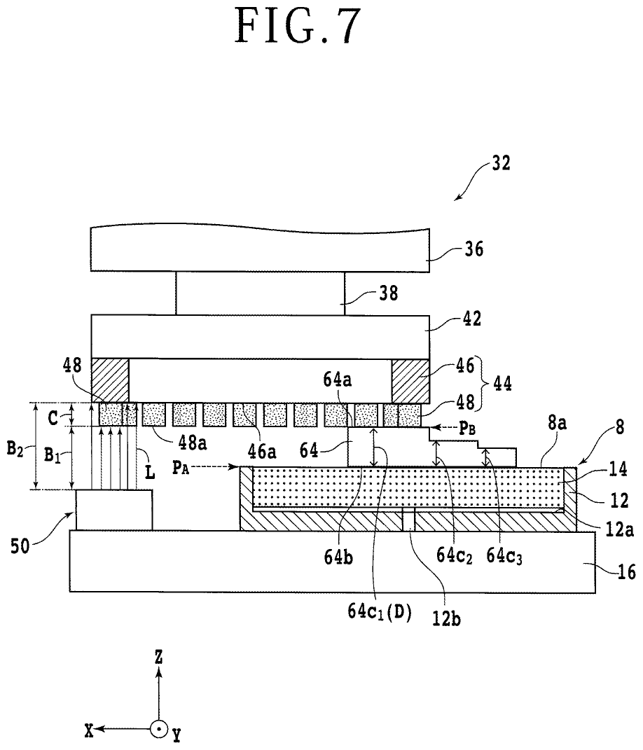

Structural details of the chuck table 8 will be described below with reference to FIG. 7. As illustrated in FIG. 7, the chuck table 8 has a frame 12 shaped as a circular plate made of ceramic or the like. The frame 12 has a circular cavity defined in an upper surface thereof and a plurality of radial fluid passages 12a defined in a bottom surface of the cavity. The frame 12 also has a central fluid channel 12b defined therein that extends vertically through the center of the bottom of the frame 12. The fluid channel 12b has an end connected to the fluid passages 12a and another end connected to a suction source, not illustrated, such as an ejector or a vacuum pump. When actuated, the suction source generates a negative pressure that is transmitted through the fluid channel 12b to the fluid passages 12a.

A circular porous plate 14 made of porous ceramic is fixedly fitted in the cavity in the frame 12. The porous plate 14 includes a substantially flat bottom surface and a conical upper surface whose central area is slightly protrusive upwardly beyond an outer circumferential portion thereof. The negative pressure generated by the suction source connected to the fluid channel 12b is transmitted through the porous plate 14 to the upper surface thereof. The upper surface of the porous plate 14 lies flush with an upper surface of the frame 12, jointly making up a holding surface 8a for holding the wafer 11 thereon under the negative pressure transmitted to the upper surface of the frame 12. The tilt adjusting mechanism adjusts the tilt of the chuck table 8, i.e., the tilt of the rotational axis 10 of the chuck table 8, to keep a portion of the holding surface 8a substantially parallel to an XY plane that is defined along the X and Y axes.

As illustrated in FIG. 1, the chuck table 8 is positioned on a rectangular table cover 16 movably disposed in the opening 4a in the base 4. The table cover 16 has both sides that face in the X-axis directions and adjoin respective bellows-shaped cover members 18 that are expandable and contractible in the opening 4a along the X-axis directions. In FIG. 1, one of the cover members is denoted by 18. The chuck table 8 is movable by the X-axis moving mechanism 6 between a loading/unloading region A1 positioned in a forward area of the opening 4a in one of the X-axis directions and a grinding region A2 positioned in a rearward area of the opening 4a in the other of the X-axis directions. When the chuck table 8 is positioned in the loading/unloading region A1, the wafer 11 is placed onto the chuck table 8.

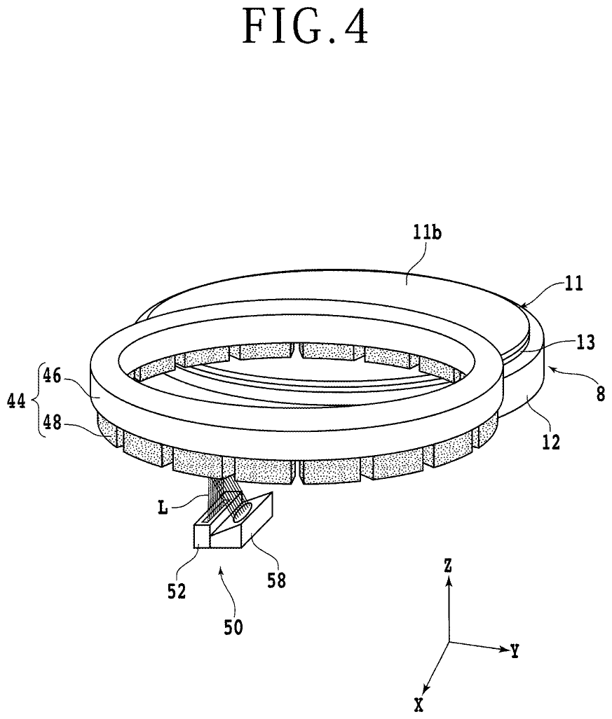

The wafer 11 includes, for example, a circular substrate of silicon having a plurality of devices, not illustrated, formed on a face side 11a thereof. However, the wafer 11 may be made of a compound semiconductor such as silicon carbide (SiC) or gallium nitride (GaN), or any of other materials. A resin-made protective tape 13 for protecting the devices is affixed to the face side 11a of the wafer 11. The wafer 11 is placed on the chuck table 8 such that the face side 11a is held under suction on the holding surface 8a through the protective tape 13 interposed therebetween. At this time, the wafer 11 has a reverse side 11b exposed upwardly (see FIG. 4).

A columnar block 20 is mounted on the base 4 behind the opening 4a. A grinding feed mechanism, i.e., a moving mechanism, 22 is mounted on a front surface of the columnar block 20. The grinding feed mechanism 22 has a pair of vertical guide rails 24 fixed to the front surface of the columnar block 20 and a Z-axis movable plate 26 slidably mounted on the guide rails 24 by a slider, not illustrated. A nut, not illustrated, is fixed to a rear surface of the Z-axis movable plate 26. A ball screw 28 that is disposed between the guide rails 24 and extends substantially parallel to the Z-axis directions is rotatably threaded through the nut.

A rotary actuator 30 such as a stepping motor is coupled to an upper end of the ball screw 28. When the rotary actuator 30 is energized to rotate the ball screw 28 about its central axis, the Z-axis movable plate 26 is moved in one of the Z-axis directions along the guide rails 24. A grinding unit 32 is fixedly mounted on a front surface of the Z-axis movable plate 26 in such a manner that the grinding unit 32 is vertically movable in the Z-axis directions in unison with the Z-axis movable plate 26 by the grinding feed mechanism 22. The grinding unit 32 is secured to the Z-axis movable plate 26 by a tubular holder 34 that is fixed to the front surface of the Z-axis movable plate 26.

The holder 34 holds therein part of a hollow cylindrical spindle housing 36 that extends substantially parallel to the Z-axis directions. The spindle housing 36 houses a cylindrical spindle 38 (see FIG. 7) rotatably therein that extends along the Z-axis directions. A rotary actuator 40 such as an electric motor is coupled to an upper end of the spindle 38. The spindle 38 has a lower end protruding downwardly from a lower end of the spindle housing 36 (see FIG. 7). A wheel mount 42 shaped as a circular plate is fixed to the lower end of the spindle 38.

An annular grinding wheel 44 is mounted on a lower surface of the wheel mount 42 by fasteners, not illustrated, such as screws. The grinding wheel 44 has an annular wheel base 46 made of a metal material such as aluminum alloy and a plurality of grindstones 48 fixed to a lower surface 46a of the wheel base 46. The grindstones 48 are arranged in an annular array circumferentially along the lower surface 46a of the wheel base 46 at spaced intervals left between adjacent ones of the grindstones 48. The grindstones 48 are formed by mixing abrasive grains of diamond, cubic boron nitride (cBN), or the like with a binder of metal, ceramic, resin, or the like, for example, and molding and sintering the mixture.

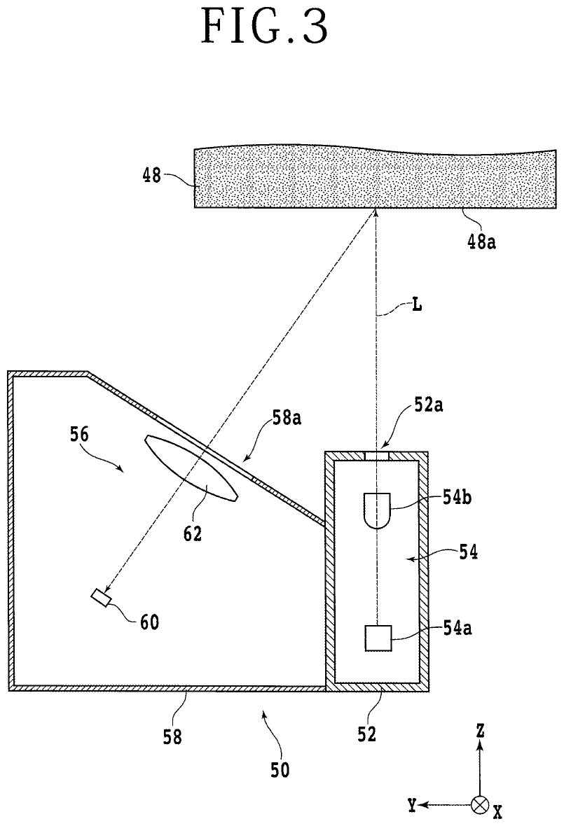

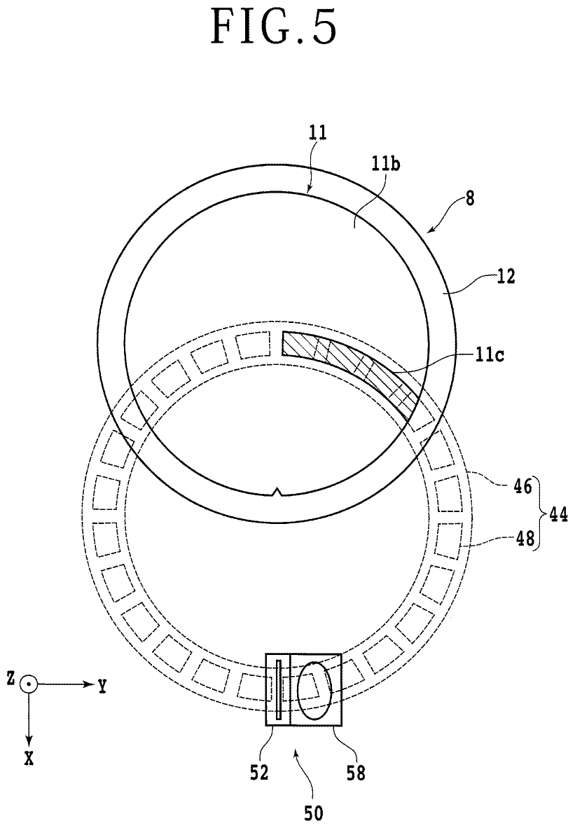

Beneath the grinding unit 32, there is disposed a grinding water supply nozzle, not illustrated, for supplying grinding water such as pure water to a contact area 11c (see FIG. 5) of the wafer 11 that is contacted by the grindstones 48 while the wafer 11 is being ground. As illustrated in FIG. 2, a laser displacement gage, i.e., a detector, 50 is disposed on a rear portion of the table cover 16 behind the chuck table 8. FIG. 2 illustrates in enlarged perspective the chuck table 8 and the laser displacement gage 50 on the table cover 16. FIG. 3 illustrates in side elevation, partly in cross section, a general make-up of the laser displacement gage 50.

As illustrated in FIG. 3, the laser displacement gage 50 has a light emitter 54 housed in a casing 52 shaped as a rectangular parallelepiped. The light emitter 54 has a light-emitting element 54a such as a semiconductor laser, i.e., a laser diode, that emits a laser beam having a predetermined wavelength. The laser beam emitted from the light-emitting element 54a is applied to a laser line generator, hereinafter referred to as a lens 54b, such as a Powell lens, a Lineman lens, or a cylindrical lens.

The lens 54b shapes the applied laser beam into a web-shaped laser beam, also referred to as a laser line beam, L having a predetermined length in a direction, i.e., one of the X-axis directions, perpendicular to the direction in which the laser beam L travels, i.e., one of the Z-axis directions, the laser beam L having a uniform output power level along the X-axis direction. The casing 52 has a rectangular opening 52a that is defined in an upper end thereof and that has a longitudinal axis along the X-axis direction. The web-shaped laser beam L is emitted through the opening 52a toward an object, i.e., the grindstones 48 and the wheel base 46 according to the present embodiment. When the laser beam L is applied to the object, it is diffusively reflected as a reflected laser beam that is detected by a light detector 56.

The light detector 56 is housed in a casing 58 disposed adjacent to the casing 52 in one of the Y-axis directions. The casing 52 has a circular opening 58a defined in an upper wall thereof for receiving the reflected laser beam from the object. The light detector 56 has a condensing lens 62 that converges the reflected laser beam coming through the opening 58a onto a complementary-metal-oxide-semiconductor (CMOS) sensor, i.e., a light-detecting element, 60 housed in the casing 58. The condensing lens 62 may be a single lens or a plurality of lenses such as an Ernostar lens. The CMOS sensor 60 has a two-dimensional array of photoelectric transducers, not illustrated.

Each of the photoelectric transducers includes a photosensor such as a phototransistor, for example. Each of the photoelectric transducers photoelectrically converts the reflected laser beam from the object at a predetermined sampling period into a voltage signal depending on the amount of light received. The voltage signal, i.e., an analog signal, is converted into a digital signal by a predetermined processing circuit, not illustrated, having an analog-to-digital converter (ADC) or the like. The digital signal is processed by a control unit 70 (see FIG. 1) to be described later.

As illustrated in FIG. 4, the laser displacement gage 50 applies the laser beam L from below the grinding wheel 44 to the grinding wheel 44 such that the longitudinal axis of the web-shaped laser beam L extends radially of the wheel base 46. Specifically, as illustrated in FIG. 7, the laser beam L is applied to a lower surface 48a of at least one of the grindstones 48 and a portion of the lower surface 46a of the wheel base 46 that is adjacent to the at least one of the grindstones 48 radially of the grinding wheel 44, i.e., the wheel base 46.

The laser beam L is then diffusively reflected by the lower surface 48a of at least one of the grindstones 48 and the adjacent portion of the lower surface 46a of the wheel base 46, and detected by the CMOS sensor 60. Since the position where the CMOS sensor 60 detects the reflected laser beam varies depending on the distance from the light emitter 54 to the position on the object where the laser beam L is reflected, the distance from the light emitter 54 to the position on the object where the laser beam L is reflected can be measured depending on the position where the CMOS sensor 60 detects the reflected laser beam, by way of triangulation.

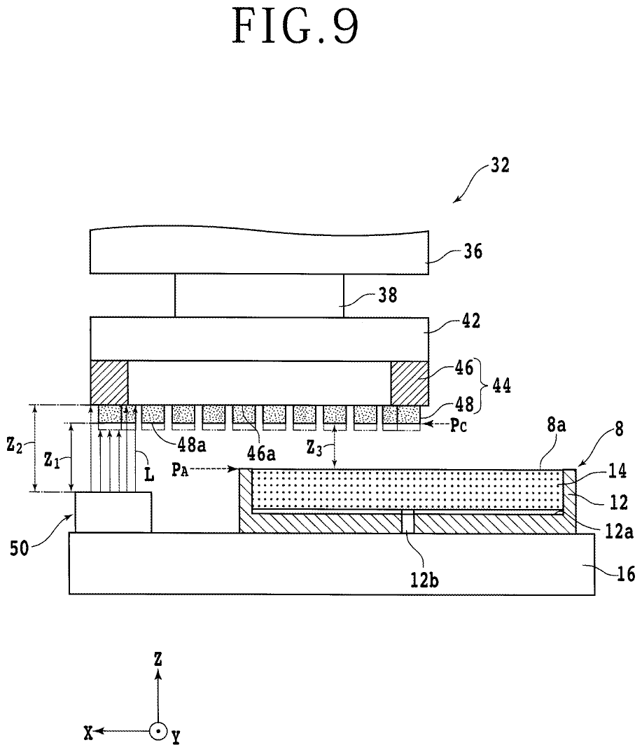

For example, when the grinding wheel 44 is placed at a vertical position that is 60 mm to 90 mm spaced from the laser displacement gage 50 along the Z-axis directions, a first distance B₁ (see FIG. 7) and a first distance Z₁ (see FIG. 9) from the laser displacement gage 50 to the lower surface 48a of the grindstone 48 are measured. Similarly, a second distance B₂ (see FIG. 7) and a second distance Z₁ (see FIG. 9) from the laser displacement gage 50 to the adjacent portion of the lower surface 46a of the wheel base 46 are measured. The protrusive distance by which the grindstone 48 protrudes from the wheel base 46, i.e., a grinding edge length also referred to as a segment height, is calculated from the difference between the first distance B₁ and the second distance B₂ or the distance between the first distance Z₁ and the second distance Z₂.

FIG. 4 illustrates in enlarged perspective the chuck table 8, the grinding wheel 44, and the laser displacement gage 50. FIG. 5 illustrates in plan the chuck table 8, the grinding wheel 44, and the laser displacement gage 50. In FIG. 5, the grinding wheel 44 is indicated by the broken lines. As illustrated in FIG. 1, the grinding apparatus 2 includes a control unit 70 for controlling operation of the X-axis moving mechanism 6, the rotary actuators, the tilt adjusting mechanism, the suction source, the chuck table 8, the grinding feed mechanism 22, the grinding unit 32, the laser displacement gage 50, etc.

The control unit 70 includes a computer including a processor, i.e., a processing device, typically a central processing unit (CPU), and a memory, i.e., a storage device. The storage device includes a main storage unit such as a dynamic random access memory (DRAM), a static random access memory (SRAM), or a read only memory (ROM), and an auxiliary storage unit such as a flash memory, a hard disk drive, or a solid state drive.

The auxiliary storage unit stores pieces of software including predetermined programs. When the processing device, etc. is operated according to the pieces of software stored in the auxiliary storage, it realizes the functions of the control unit 70. A part of the auxiliary storage unit functions as a holding surface position storing section 72 for storing a relative vertical position P_{A} of the holding surface 8a with respect to the grinding wheel 44 in one of the Z-axis directions. According to the present embodiment, the holding surface position storing section 72 stores the relative vertical position P_{A} of the holding surface 8a with respect to the grinding wheel 44 at the time at which the lower surface 48a of the grindstone 48 contacts a reference piece 64 (see FIG. 7) placed on the holding surface 8a.

The control unit 70 can grasp the distance that the grinding wheel 44 is moved along the Z-axis directions, by controlling the rotary actuator 30. Therefore, once the relative vertical position P_{A} of the holding surface 8a has been stored in the holding surface position storing section 72, the control unit 70 can subsequently grasp the relative height of the grinding wheel 44, e.g., the lower surface 46a of the wheel base 46, at all times unless the chuck table 8 is replaced or the holding surface 8a is corrected in shape.

The programs stored in the auxiliary storage unit will be described below. A first program is stored in the auxiliary storage unit. When the first program is executed by the processing device, it functions as a first distance calculating section 74 for calculating a distance (the first distance B₁ (see FIG. 7) or a first distance Z₁ (see FIG. 9)) along the Z-axis directions from the laser displacement gage 50 to the lower surface 48a of the grindstone 48 depending on the position where the CMOS sensor 60 detects the reflected laser beam. A second program is also stored in the auxiliary storage unit. When the second program is executed by the processing device, it functions as a lower surface position calculating section 76 for calculating a vertical position P_{C} (see FIG. 9) of the lower surface 48a of the grindstone 48 with respect to the holding surface 8a on the basis of the vertical position P_{A} stored in the holding surface position storing section 72, the first distance B₁, etc. A process of calculating the vertical position P_{C} will be described later.

Further, a third program is stored in the auxiliary storage unit. When the third program is executed by the processing device, it functions as a grinding edge length calculating section 78. The grinding edge length calculating section 78 calculates the grinding edge length C (see FIG. 7) of the grindstone 48 on the basis of the second distance B₂ (see FIG. 7) from the laser displacement gage 50 to the lower surface 46a of the wheel base 46 and the first distance B₁. Moreover, the grinding edge length calculating section 78 can calculate the grinding edge length C of the grindstone 48 on the basis of the second distance Z₂ (see FIG. 9) from the laser displacement gage 50 to the lower surface 46a of the wheel base 46 and the first distance Z₁ (see FIG. 9), for example. Specifically, the grinding edge length calculating section 78 calculates the grinding edge length C directly above the laser displacement gage 50 by subtracting the first distance Z₁ or B₁ from the second distance Z₂ or B₂.

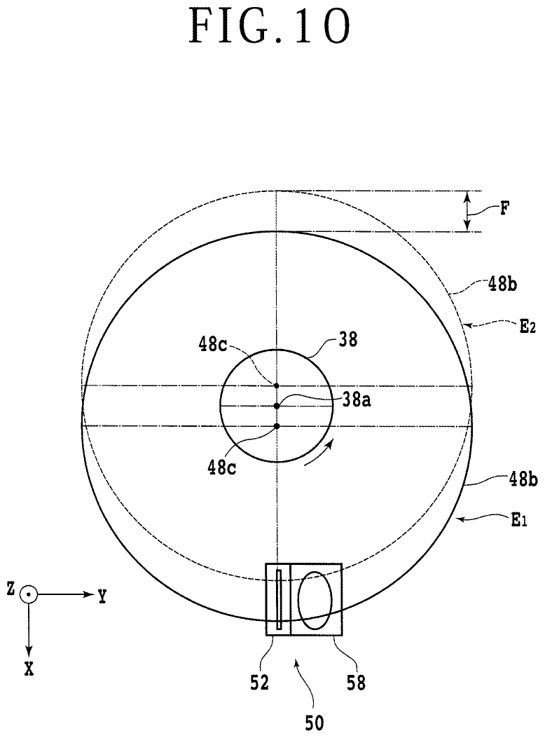

Moreover, a fourth program is stored in the auxiliary storage unit. When the fourth program is executed by the processing device, it functions as a center deviation calculating section 80 for calculating a deviation of the center, denoted by 48c in FIG. 10, of a circle defined by an outer circumferential side surface 48b of the grindstones 48 from the center, denoted by 38a in FIG. 10, of rotation of the spindle 38, on the basis of data of the reflected laser beam detected by the laser displacement gage 50 at the time at which the grinding wheel 44 is rotated about its central axis. A process of calculating the deviation will be described later. For grinding the wafer 11 on the grinding apparatus 2, the X-axis moving mechanism 6 moves and places the chuck table 8 in the loading/unloading region A1. Then, after the face side 11a of the wafer 11 is held under suction on the holding surface 8a, the X-axis moving mechanism 6 moves the chuck table 8 to the grinding region A2. Thereafter, the rotary actuator associated with the chuck table 8 is energized to rotate the chuck table 8 in a predetermined direction about the rotational axis 10.

In addition, while the grinding water supply nozzle is supplying grinding water to the contact area 11c of the wafer 11 and the rotary actuator 40 is rotating the grinding wheel 44 in a predetermined direction about its central axis, the grinding feed mechanism 22 lowers the grinding unit 32 at a predetermined speed in one of the Z-axis directions. The chuck table 8 and the grinding unit 32 are thus relatively moved along the Z-axis directions to move the holding surface 8a and the grinding wheel 44 closer to each other until the lower surfaces 48a of the grindstones 48 abrasively contact the reverse side 11b of the wafer 11, whereupon the grindstones 48 start grinding the reverse side 11b of the wafer 11. Prior to thus grinding the wafer 11, a process, known as a setting-up process, is carried out to enable the grinding apparatus 2 to recognize the position of the lower surfaces 48a of grindstones 48 with respect to the holding surface 8a of the chuck table 8 as a vertical or heightwise reference, i.e., a home position.

The setting-up process for the grinding apparatus 2 will be described below. Usually, a manual setting-up process is performed in the setting-up process for the grinding apparatus 2. In the manual setting-up process, the operator places a reference piece, i.e., a block gage, 64 (see FIG. 7) having a predetermined thickness in a predetermined area on the holding surface 8a. Then, the grinding feed mechanism 22 lowers, i.e., grinding-feeds, the grinding unit 32 to bring the lower surfaces 48a of the grindstones 48 into abrasive contact with a predetermined upper surface 64a of the reference piece 64. Now, the grinding apparatus 2 recognizes the position of the lower surfaces 48a of the grindstones 48 with respect to the holding surface 8a as a vertical or heightwise reference.

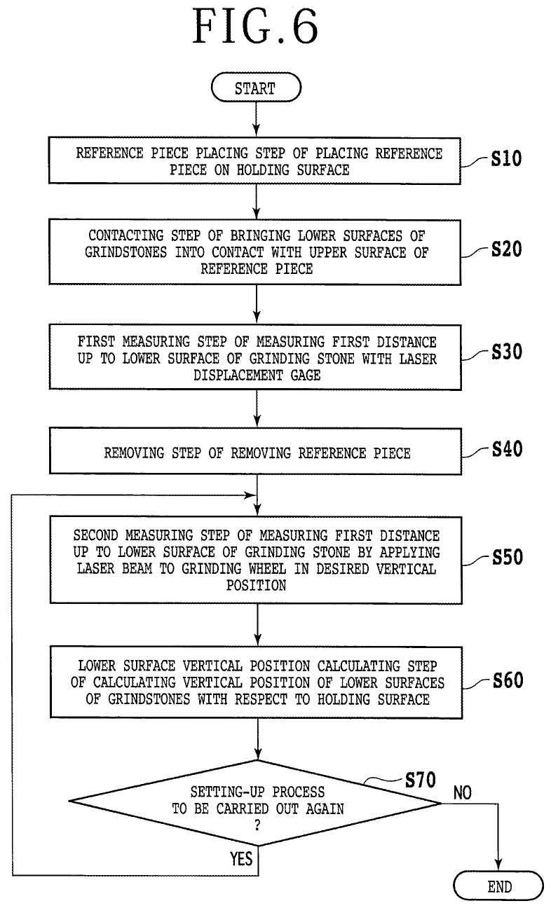

However, the manual setting-up process requires the operator to work in an increased number of man-hours. Each time the manual setting-up process is performed, the grinding apparatus 2 or the grinding wheel 44 may possibly be damaged by a mistake that the operator may make while working due to the manual setting-up process. According to the present embodiment, as illustrated in FIG. 6, in a first cycle of the setting-up process, the manual setting-up process is carried out using the reference piece 64 (steps S10 through S30). In second and subsequent cycles of the setting-up process, however, the manual setting-up process using the reference piece 64 is not carried out, i.e., the reference piece 64 is not used, but only the laser displacement gage 50 is used (step S50).

According to the present embodiment, consequently, the number of man-hours required for the operator to place the reference piece 64 on the holding surface 8a and then retrieve the reference piece 64 from the holding surface 8a is eliminated. Further, the possibility that the operator may make a mistake in the manual setting-up process is lowered. In other words, the possibility that the grinding apparatus 2 or the grinding wheel 44 may be damaged by the reference piece 64 due to a mistake that the operator might make while working in the manual setting-up process is lowered. FIG. 6 is a flowchart of the setting-up process for the grinding apparatus 2 according to the present embodiment. In reference piece placing step S10 illustrated in FIG. 6, the operator manually places the reference piece 64 in the predetermined area on the holding surface 8a that corresponds to the contact area 11c. As illustrated in FIG. 7, the reference piece 64 has a substantially flat lower surface 64b and a substantially stepped upper surface 64a.

The distance from the lower surface 64b to the upper surface 64a varies stepwise. For example, the reference piece 64 has a thickest region having a thickness 64c₁ of 5.05 mm, a second thickest region having a thickness 64c₂ of 5.02 mm, and a thinnest region having a thickness 64c₃ of 5.00 mm. According to the present embodiment, the thickest region of the reference piece 64 is used for measurement. However, it is up to the operator to select which one of the regions having the different thicknesses is to be used. The operator inputs the thickness D of the region of the reference piece 64 to be used to the control unit 70 through an input device, not illustrated, such as a touch panel.

After reference piece placing step S10, the grinding unit 32 disposed above the chuck table 8 is lowered to bring the lower surfaces 48a of those grindstones 48 that are disposed in a position different from the position directly above the laser displacement gage 50 into contact with the upper surface 64a of the reference piece 64 disposed in a relative position P_{B} with respect to the holding surface 8a in one of the Z-axis directions (contacting step S20). In contacting step S20, the holding surface position storing section 72 stores the relative vertical position P_{A} of the holding surface 8a with respect to the grinding wheel 44 in the Z-axis direction at the time at which the lower surfaces 48a contact the reference piece 64.

After contacting step S20 or simultaneously with contacting step S20, the laser displacement gage 50 measures the first distance B₁ up to the lower surface 48a of the corresponding grindstone 48 (first measuring step S30). FIG. 7 illustrates first measuring step S30 in side elevation, partly in cross section. After first measuring step S30, the reference piece 64 is removed from the holding surface 8a (removing step S40). While the setting-up process is being performed from reference piece placing step S10 to removing step S40, the spindle 38 of the grinding unit 32 and the chuck table 8 are not rotated.

After removing step S40, the wafer 11 is ground, for example. Since the lower surfaces 48a of the grindstones 48 are worn as they grind the wafer 11, the grinding edge length C of the grindstones 48 is shortened (see FIG. 9). With the grinding edge length C thus shortened, even though the grinding wheel 44 is disposed in the vertical position reached in contacting step S20, the distance from the lower surfaces 48a to the holding surface 8a is different from the thickness D. In this case, it is necessary to perform the setting-up process again for highly accurately grinding the wafer 11.

When the lower surfaces 48a of the grindstones 48 are worn, the first distance Z₁ (see FIG. 9) from the laser displacement gage 50 to the lower surface 48a and the distance Z₃ from the holding surfaces 8a to the lower surfaces 48a are respectively increased in the same way. The distance Z₃ is represented by a primary function of the first distance Z₁ where the coefficient, i.e., the gradient, is 1. When the first distance Z₁ is equal to the first distance Bᵢ, the distance Z₃ is equal to the thickness D. According to the present embodiment, further, D<B₁, i.e., the laser displacement gage 50 is positioned below the holding surface 8a. The first distance Z₁ and the distance Z₃ are related to each other according to the following equation (1).

Z₃=Z₁−(B₁−D) (1)

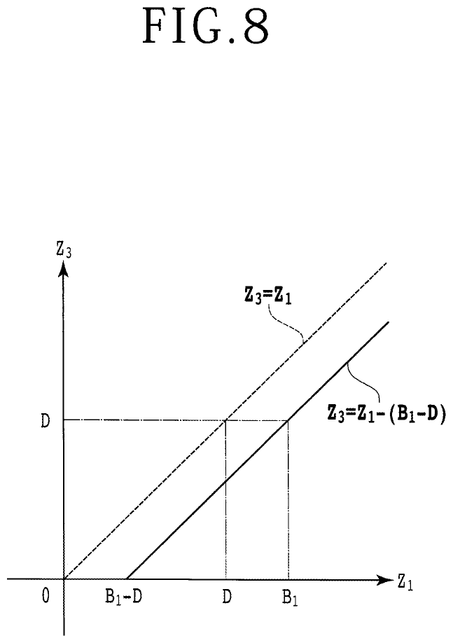

FIG. 8 is a graph illustrating the distance from the holding surface 8a and the laser displacement gage 50 to the lower surfaces 48a of the grindstones 48. After the distance Z₃ has been calculated, the vertical position P_{C} of the lower surfaces 48a of the grindstones 48 with respect to the holding surface 8a is calculated according to the following equation (2).

P_{C}=P_{A}+Z₃ (2)

The lower surface position calculating section 76 has programs representing the equations (1) and (2), respectively, and can calculate the vertical position P_{C} of the lower surfaces 48a with respect to the holding surface 8a from the first distance B₁, the thickness D, the relative vertical position P_{A}, and the first distance Z₁. For calculating the vertical position P_{C} of the lower surfaces 48a with respect to the holding surface 8a after the wafer 11 has been ground, the laser beam L is applied to the grinding wheel 44 disposed in a desired vertical position, and the first distance Z₁ from the laser displacement gage 50 to the lower surface 48a of the corresponding grindstone 48 is measured (second measuring step S50).

FIG. 9 illustrates second measuring step S50 in side elevation, partly in cross section. After the first distance Z₁ has been measured in second measuring step S50, the lower surface position calculating section 76 can calculate the vertical position P_{C} of the lower surfaces 48a of the grindstones 48 in second measuring step S50 with respect to the holding surface 8a, as described above (lower surface vertical position calculating step S60). In second measuring step S50, the setting-up process is carried out using the laser displacement gage 50, but not the reference piece 64. Therefore, the number of man-hours required for the operator to place the reference piece 64 on the holding surface 8a and then retrieve the reference piece 64 from the holding surface 8a is eliminated.

Further, the possibility that the operator may make a mistake in the manual setting-up process is lowered. In other words, the possibility that the grinding apparatus 2 or the grinding wheel 44 may be damaged by the reference piece 64 due to a mistake that the operator might make while working in the manual setting-up process is lowered. Inasmuch as the reference piece 64 is not used in second measuring step S50, second measuring step S50 is advantageous in that the setting-up process can be performed while the wafer 11 is being ground and also while the grinding wheel 44 is being rotated. In other words, the setting-up process can be performed while the chuck table 8 and the grinding wheel 44 are being rotated.

While the grinding wheel 44 is being rotated, the web-shaped laser beam L is applied to the lower surfaces 48a of the grindstones 48 and the respective portions of the lower surface 46a of the wheel base 46 that are adjacent to the grindstones 48 radially of the grinding wheel 44. After lower surface vertical position calculating step S60, if the setting-up process is to be carried out again using the laser displacement gage 50, but not the reference piece 64 (YES in step S70), then control goes back to second measuring step S50. On the other hand, if the setting-up process is not to be carried out (NO in step S70), then the flowchart illustrated in FIG. 5 is ended.

The center deviation calculating section 80 of the control unit 70 calculates a deviation of the center 48c of the circle defined by the outer circumferential side surface 48b of the grindstones 48 from the center 38a of rotation of the spindle 38 during second measuring step S50 (see FIG. 10). FIG. 10 illustrates a deviation of the center 48c of the circle defined by the outer circumferential side surface 48b of the grindstones 48 from the center 38a of rotation of the spindle 38. A deviation, i.e., an off-center distance, between the center 38a of rotation and the center 48c occurs when the grinding wheel 44 is mounted on the wheel mount 42, and is of approximately 100 μm, for example.

In FIG. 10, where the grinding apparatus 2 is viewed in plan, the outer circumferential side surface 48b of the grindstones 48 at the time at which the grinding wheel 44 is positioned in a rearmost position E₁ is indicated by the solid line, and the outer circumferential side surface 48b of the grindstones 48 at the time at which the grinding wheel 44 is positioned in a foremost position E₂ is indicated by the broken line. With the center 48c thus deviating from the center 38a of rotation, the outer circumferential edge of the lower surface 48a of the grindstone 48 that is positioned directly above the laser displacement gage 50 varies in position upon rotation of the grinding wheel 44.

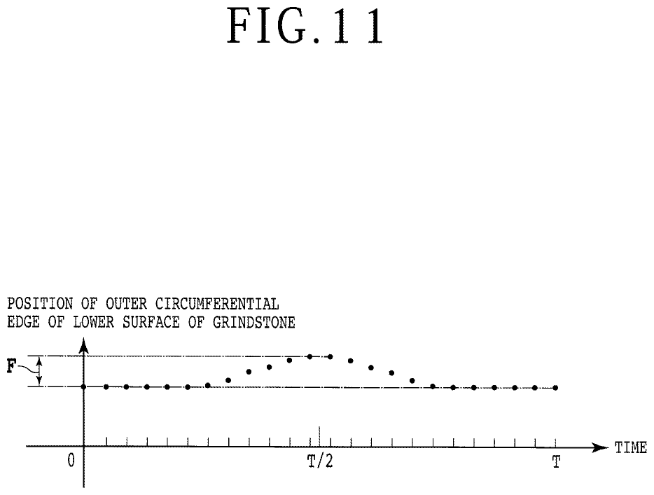

FIG. 11 is a graph illustrating variations over time in the position of the outer circumferential edge of the lower surface 48a of the grindstone 48. In FIG. 11, the horizontal axis represents time, and the vertical axis represents the position of the outer circumferential edge of the lower surface 48a of the grindstone 48 that is positioned directly above the laser displacement gage 50. As illustrated in FIG. 11, the grinding wheel 44 is positioned in the foremost position E₂ at time 0 and time T, and in the rearmost position E₁ at time T/2. The center deviation calculating section 80 calculates a distance F between the position of the outer circumferential edge of the lower surface 48a at the time at which the grinding wheel 44 is in the foremost position E₂ and the position of the outer circumferential edge of the lower surface 48a at the time at which the grinding wheel 44 is in the rearmost position E₁, depending on the position where the CMOS sensor 60 detects the reflected laser beam.

Since the deviation between the center 38a of rotation and the center 48c corresponds to half the distance F, the deviation can be calculated when the center deviation calculating section 80 has calculated F/2 (deviation calculating step). The calculated deviation is displayed on a display device, not illustrated, such as a touch panel on the grinding apparatus 2. In a case where the deviation between the center 38a of rotation and the center 48c is not zero, the operator may correct the position of the center 48c of the outer circumferential side surface 48b. For example, the operator may correct the position of the center 48c by hammering the side surface of the grinding wheel 44 while the grinding unit 32 is not in operation.

Alternatively, the operator may correct the position of the center 48c by pressing a dressing member against the outer circumferential side surface 48b while the grinding wheel 44 is being rotated at a predetermined rotational speed.

The structure, method, etc. according to the above embodiment may be changed or modified appropriately without departing from the scope of the present invention.

The present invention is not limited to the details of the above described preferred embodiment. The scope of the invention is defined by the appended claim and all changes and modifications as fall within the equivalence of the scope of the claim are therefore to be embraced by the invention.

What is claimed is:

1. A grinding apparatus for grinding a workpiece, comprising:
a chuck table rotatable about a predetermined rotational axis, the chuck table having a holding surface for holding the workpiece thereon;
a grinding unit that is disposed above the chuck table and has a spindle, wherein a grinding wheel is to be mounted on a lower end of the spindle and the grinding wheel includes an annular wheel base and a plurality of grindstones disposed on a lower surface of the wheel base circumferentially therealong;
a moving mechanism for moving the chuck table and the grinding unit relatively to each other in predetermined directions to bring the holding surface and the grinding wheel closer to each other;
a detector having a light emitter and a light detector, wherein the light emitter includes a lens and a light-emitting element and the light emitter can apply a web-shaped laser beam to at least one of the grinding stones and a portion of the lower surface of the wheel base that is adjacent to the at least one of the grindstones radially of the grinding wheel, the light detector including a light-detecting element for detecting a reflected laser beam reflected of the web-shaped laser beam from the at least one of the grinding stones and the portion of the lower surface of the wheel base; and
a control unit for controlling the grinding unit, the moving mechanism, and the detector, the control unit having a processor and a memory,
wherein the control unit includes
a holding surface position storing section for storing a relative vertical position of the holding surface with respect to the grinding wheel along the predetermined directions,
a first distance calculating section for calculating a first distance in one of the predetermined directions from the detector to a lower surface of the at least one of the grindstones, and
a lower surface position calculating section for calculating a position of the lower surface of the at least one of the grindstones with respect to the holding surface on a basis of the relative vertical position of the holding surface stored in the holding surface position storing section and the first distance calculated by the first distance calculating section.

2. The grinding apparatus according to claim 1,
wherein it is assumed that, when a grindstone of the plurality of grindstones is held in contact with an upper surface of a reference piece placed on the holding surface, the relative vertical position in one of the predetermined directions of the holding surface with respect to the grinding wheel is represented by P_{A}, the thickness from the upper surface of the reference piece to a lower surface thereof is represented by D, and the first distance from the detector to the lower surface of the at least one of the grindstones is represented by B₁, and that, when the reference piece is removed from the holding surface, the first distance from the detector to the lower surface of the at least one of the grindstones is represented by Z₁, and
the lower surface position calculating section calculates the vertical position P_{C} of the lower surface of the at least one of the grindstones with respect to the holding surface when the reference piece is removed from the holding surface, according to the equation (1)
Z₃=Z₁−(B₁−D) (1)
and the equation (2)
P_{C}=P_{A}+Z₃ (2).

3. The grinding apparatus according to claim 1, wherein the control unit further includes
a grinding edge length calculating section for calculating a grinding edge length of the at least one of the grindstones on a basis of a second distance from the detector to the lower surface of the wheel base and the first distance from the detector to the lower surface of the at least one of the grindstones.

4. The grinding apparatus according to claim 1, wherein the control unit further includes
a center deviation calculating section for calculating a deviation between a center of rotation of the spindle and a center of a circle defined by an outer circumferential side surface of the grindstones on a basis of data of the reflected laser beam detected by the detector at a time at which the grinding wheel is rotated about its central axis.
